(19) United States
(12) Patent Application Publication
(10) Pub. No.: US 2017/0250197 A1
(43) Pub. Date: Aug. 31, 2017

(54) LAYOUT STRUCTURE FOR SEMICONDUCTOR INTEGRATED CIRCUIT

(71) Applicant: SOCIONEXT INC., Kanagawa (JP)

(72) Inventor: Hiroyuki SHIMBO, Kyoto (JP)

(21) Appl. No.: 15/592,877

(22) Filed: May 11, 2017

Related U.S. Application Data
(63) Continuation of application No. PCT/JP2015/005004, filed on Oct. 1, 2015.

(30) Foreign Application Priority Data
Nov. 14, 2014 (JP) 2014-231678

(51) Int. Cl. H01L 27/12; H01L 27/06; H01L 27/02; H01L 23/66; H01L 23/528

(52) U.S. Cl. CPC H01L 27/1203; H01L 23/66; H01L 23/528; H01L 27/0207; H01L 27/0629; H01L 2223/6677

(57) ABSTRACT

In a circuit block, a plurality of standard cells are arranged to form a circuit of silicon-on-insulator (SOI) transistors. Also arranged in the circuit block is a capacitor cell including a capacitor arranged between a power supply line for supplying VDD and a power supply line for supplying VSS. An antenna cell, including an antenna diode formed between either of the two power supply lines and either a substrate or a well, is arranged adjacent to the capacitor cell.

### CROSS-REFERENCE TO RELATED APPLICATION

This is a continuation of International Application No. PCT/JP2015/005004 filed on Oct. 1, 2015, which claims priority to Japanese Patent Application No. 2014-231678 filed on Nov. 14, 2014. The entire disclosures of these applications are hereby incorporated by reference.

### BACKGROUND

The present disclosure relates to a layout structure for a semiconductor integrated circuit including transistors with a silicon-on-insulator (SOI) structure (hereinafter referred to as “SOI transistors”).

FIG. 7 is a cross-sectional view illustrating a configuration for an SOI transistor. As shown in FIG. 7, the SOI transistor includes a buried insulator (typically a buried oxide) 61 in a substrate or a well, a silicon thin film 62 formed on the buried insulator 61, and a transistor device comprised of a gate G, a source S, and a drain D on the silicon thin film 62. This structure tends to intensify an electric field generated in a channel region between the source and drain, thus contributing to the performance enhancement of the transistor. Note that a type of SOI structure having so thin a silicon film 62 as to fully deplete the channel region is called a fully-depleted silicon-on-insulator (FD-SOI).

Meanwhile, a semiconductor device manufacturing process may sometimes cause a so-called “antenna error.” The antenna error refers to a phenomenon that a transistor's gate dielectric under its gate electrode suffers either breakdown or damage due to the influx, into the gate electrode, of electric charges generated by plasma in the ambient during the manufacturing process of the transistor and collected in the metal wires of the transistor that are electrically connected to the gate electrode. In the case of an SOI transistor, the possibility of such antenna errors' occurring in not only the gate dielectric but also the buried insulator under the source or drain needs to be taken into account. The reason is that those electric charges collected in the metal wires of the transistor being manufactured also flow into the source or drain electrically connected to the metal wires to cause breakdown or damage to the buried insulator under a doped layer serving as the source or drain.

Thus, in order to avoid causing such antenna errors in an SOI transistor, Japanese Unexamined Patent Publication No. 2003-133559 discloses a technique for inserting an antenna diode for dissipating those electric charges into the substrate.

Japanese Unexamined Patent Publication No. 2003-133559, however, fails to disclose actually how to insert such an antenna diode into a semiconductor integrated circuit including SOI transistors.

The present disclosure provides a layout structure for a semiconductor integrated circuit including SOI transistors with such antenna errors that could occur in the buried insulator under the source or drain taken into account.

### SUMMARY

An aspect of the present disclosure is a layout structure for a semiconductor integrated circuit including silicon-on-insulator (SOI) transistors. The structure includes a circuit block in which a plurality of standard cells are arranged, thereby forming a circuit of the SOI transistors. The circuit block includes a capacitor cell including a capacitor arranged between a first power supply line for supplying a supply potential and a second power supply line for supplying a ground potential. The capacitor cell includes an antenna diode formed between either the first or second power supply line and either a substrate or a well. Alternatively, an antenna cell, including an antenna diode formed between either the first or second power supply line and either the substrate or the well, is arranged adjacent to the capacitor cell.

According to this aspect, in a circuit block in which a plurality of cell rows are arranged, a capacitor cell including a capacitor is arranged between a first power supply line for supplying a supply potential and a second power supply line for supplying a ground potential. The capacitor cell is inserted as a countermeasure against a power supply noise. The capacitor cell includes an antenna diode formed between either the first or second power supply line and either a substrate or a well. Alternatively, an antenna cell, including an antenna diode formed between either the first or second power supply line and either the substrate or the well, is arranged adjacent to the capacitor cell. Such a layout structure is implemented by placement of a capacitor cell with an antenna diode or placement of a capacitor cell adjacent to an antenna cell during the physical design of a circuit block. This may prevent the designer from failing to insert an antenna diode due to a human error, thus reliably avoiding causing antenna errors.

The present disclosure provides a technique for reliably avoiding causing antenna errors by preventing the designer from failing to insert an antenna diode into a semiconductor integrated circuit with SOI transistors.

### BRIEF DESCRIPTION OF THE DRAWINGS

FIG. 1A is a plan view illustrating an exemplary layout structure for a semiconductor integrated circuit according to an embodiment, and FIG. 1B is a plan view illustrating an exemplary configuration for a capacitor cell with antenna diodes included in the layout structure shown in FIG. 1A.

FIG. 2 is a plan view illustrating a detailed structure of a circuit block including capacitor cells with antenna diodes.

FIG. 3 is a cross-sectional view illustrating a detailed structure of a circuit block including capacitor cells with antenna diodes.

FIG. 4 illustrates another exemplary configuration for a capacitor cell with antenna diodes.

FIGS. 5A and 5B illustrate other exemplary configurations for capacitor cells with antenna diodes.

FIG. 6 illustrates still another exemplary configuration for a capacitor cell with antenna diodes.

FIG. 7 is a cross-sectional view illustrating an SOI transistor.

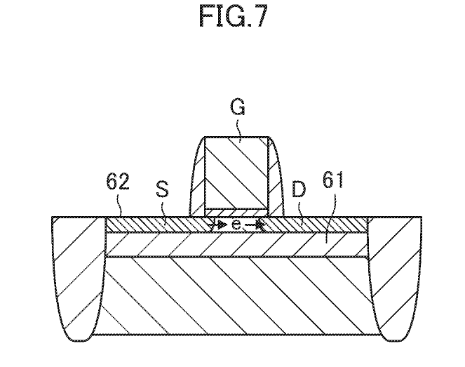

### DETAILED DESCRIPTION

Embodiments of the present disclosure will now be described with reference to the accompanying drawings.

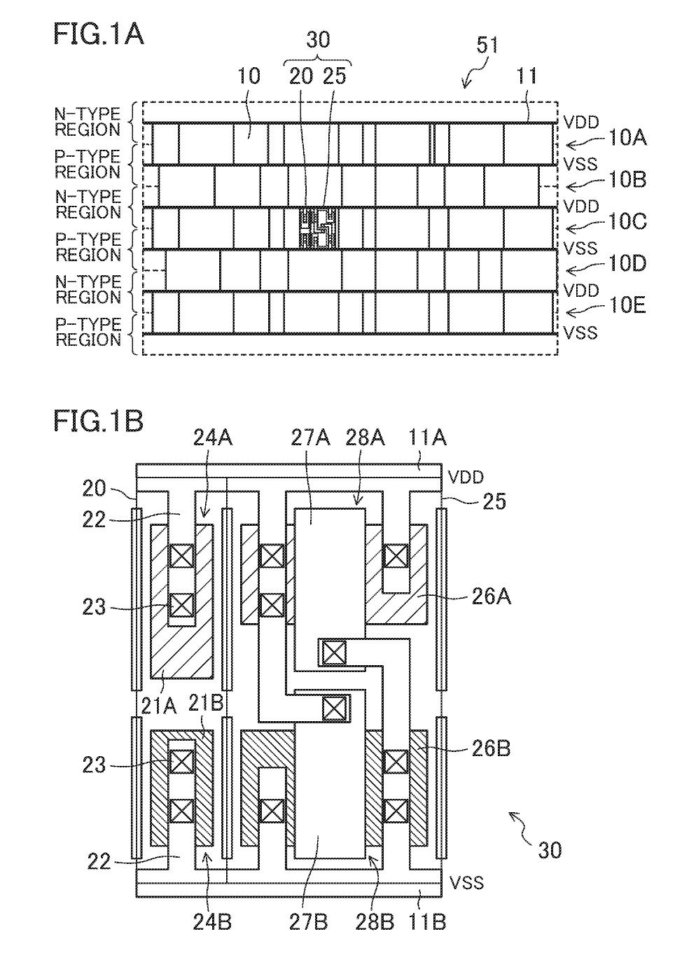

FIG. 1A is a plan view illustrating an exemplary layout structure for a semiconductor integrated circuit according to an embodiment. In FIG. 1A, schematically illustrated is a single circuit block 51 for a semiconductor integrated circuit. In this circuit block 51, five cell rows 10A, 10B, 10C, 10D, and 10E, each being comprised of a plurality of standard cells 10 that are arranged side by side horizontally in FIG. 1A, are arranged vertically in FIG. 1A. Note that neither the internal configuration nor wiring of the standard cells 10 is illustrated in FIG. 1A. The transistors included in each of those standard cells 10 have the SOI structure described above. Thus, a circuit of SOI transistors is formed in this circuit block 51. Power supply lines 11 for supplying either a supply potential VDD or a ground potential VSS to the circuit block 51 are arranged to extend horizontally between the cell rows. In these cell rows 10A-10E, P-type regions where N-channel transistors are arranged alternate every row with N-type regions where

P-channel transistors are arranged. Each of the power supply lines 11 is shared by an associated pair of cell rows located over and under the power supply line. In this embodiment, an N-well to serve as an N-type region is supposed to be defined on a P-type substrate to serve as a P-type region.

In the circuit block 51 shown in FIG. 1A, an antenna cell 20 and a capacitor cell 25 are arranged adjacent to each other. As used herein, the “antenna cell” refers to a cell including an antenna diode configured to dissipate electric charges collected in a metal wire into either a substrate or a well. Also, the capacitor cell including a capacitor is arranged between a power supply line 11 for supplying a supply potential VDD and a power supply line 11 for supplying a ground potential VSS. The capacitor cell is inserted as a countermeasure against a power supply noise. In this embodiment, arranging the capacitor cell 30 with antenna diodes such as the one shown in FIG. 1B in the circuit block 51 realizes the configuration in which the antenna cell 20 and the capacitor cell 25 are arranged adjacent to each other as shown in FIG. 1A.

The capacitor cell 30 with antenna diodes shown in FIG. 1B includes doped regions 21A and 21B, which are provided directly on the substrate or well with no buried insulator interposed between them. Specifically, in this example, the doped region 21A is a region doped with a P-type dopant and defined on an N-well, while the doped region 21B is a region doped with an N-type dopant and defined on a P-type substrate. The doped region 21A is connected, via contacts 23, to an extension 22 of the power supply line 11A serving as a first power supply line for supplying the supply potential VDD. The doped region 21B is connected, via contacts 23, to an extension 22 of the power supply line 11B serving as a second power supply line for supplying the ground potential VSS. That is to say, in the capacitor cell 30 with antenna diodes shown in FIG. 1B, antenna diodes 24A, 24B are formed between the power supply lines 11A, 11B and the substrate or well.

The capacitor cell 30 with antenna diodes shown in FIG. 1B further includes doped regions 26A and 26B and gate lines 27A and 27B with a broad line width. The gate line 27A is electrically connected to the power supply line 11B. The gate line 27B is electrically connected to the power supply line 11A. That is to say, a capacitor 28A including the doped region 26A and the gate line 27A and another capacitor 28B including the doped region 26B and the gate line 27B are formed between the power supply line 11A for supplying the supply potential VDD and the power supply line 11B for supplying the ground potential VSS. In the configuration shown in FIG. 1B, the gate lines 27A and 27B, forming part of the capacitors 28A and 28B, respectively, are directly connected to the power supply lines 11B and 11A, respectively. However, this is only a non-limiting exemplary embodiment. Alternatively, the gate lines 27A and 27B may also be connected to a high-resistance element such as a TIE circuit for outputting a fixed potential.

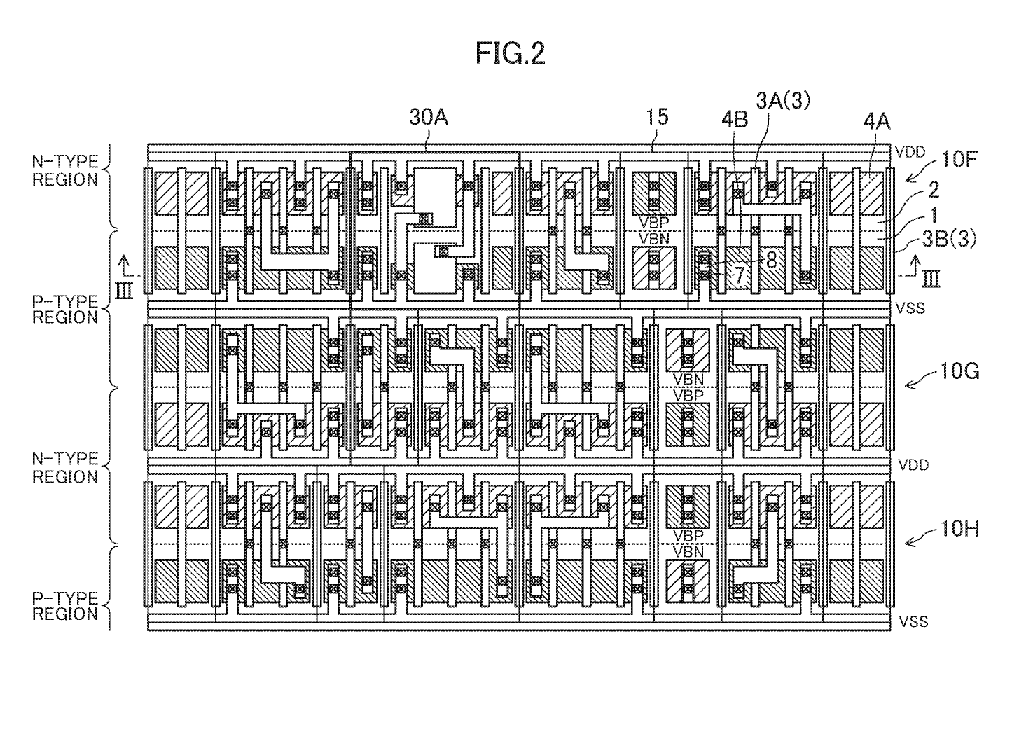

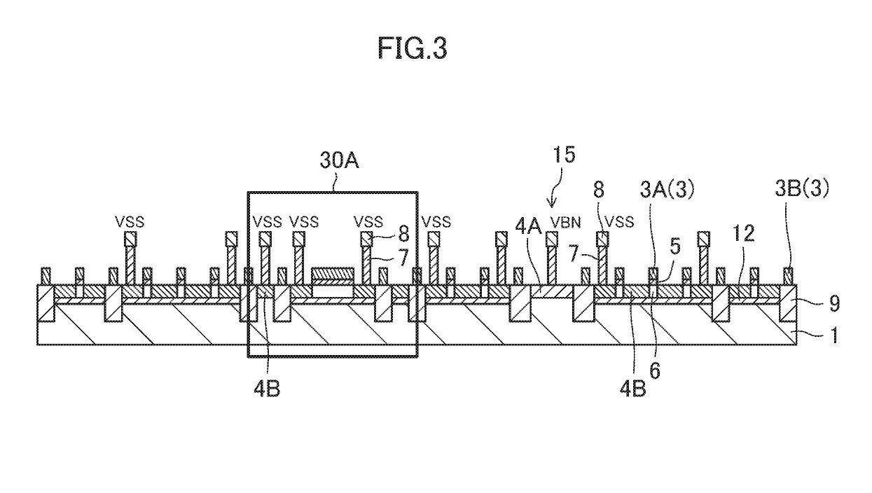

FIGS. 2 and 3 illustrate a detailed structure for a circuit block including capacitor cells with antenna diodes. FIG. 2 is a plan view illustrating a detailed layout for the circuit block, and FIG. 3 is a cross-sectional view taken along the plane III-III shown in FIG. 2. In FIG. 2, three cell rows 10F, 10G, and 10H, each extending horizontally in FIG. 2, are arranged vertically in FIG. 2. A cross section of the P-type region of the cell row 10F is illustrated in FIG. 3. As shown in FIG. 3, in the P-type region, a buried oxide 12, an exemplary buried insulator, is provided in the P-type substrate 1, and an N-type doped layer 4B to serve as a source or drain for N-channel transistors has been formed on the buried oxide 12. Although not shown in FIG. 3, in the N-type region, a buried oxide has been formed in an N-well 2, and a P-type doped layer 4A to serve as a source or drain for P-channel transistors has been formed on the buried oxide. Gates 3 are identified by the reference numeral 3 and may be made of polysilicon, for example. The gates 3 include gates 3A, each of which forms part of a transistor, and dummy gates 3B, none of which forms any transistors. A gate oxide 5 has been formed as an exemplary gate dielectric under the gate 3A of each transistor, and a channel region 6 has been defined under the gate oxide 5. A portion of the doped layer 4A, 4B to serve as a source or drain for transistors is connected to the extensions 8 of the power supply lines via contacts 7. The reference numeral 9 denotes shallow trench isolations (STIs).

A capacitor cell 30A with antenna diodes is inserted into the cell row 10F. This capacitor cell 30A with antenna diodes has a slightly different layout from, but has the same function as, the capacitor cell 30 with antenna diodes shown in FIG. 1B. The capacitor cell 30A also includes capacitors and antenna diodes. As shown in FIG. 3, in a region where there are the antenna diodes, no buried oxide 12 has been formed in the capacitor cell 30A with antenna diodes, and the doped layer 4B is directly in contact with the P-type substrate 1. A TAP cell 15 with a TAP function producing substrate potentials VBP, VBN is also inserted into the cell row 10F. No buried oxide 12 has been formed in the TAP cell 15, either, thus bringing the doped layer 4A into direct contact with the P-type substrate 1.

In the configuration shown in FIG. 1A, a capacitor cell 30 with antenna diodes is arranged in the circuit block 51. Alternatively, an antenna cell 20 is arranged adjacent to the capacitor cell 25. Now, it will be described what significance such an arrangement of a capacitor cell with antenna diodes or such an arrangement of an antenna cell adjacent to a capacitor cell has according to the present disclosure.

A semiconductor integrated circuit comprised of SOI transistors should avoid generating antenna errors in not only its gate dielectric but also the buried insulator under its doped layer as well. For example, when power supply lines are formed for an M1 layer (that is the lowest-level metal interconnect layer) within the circuit block, electric charges collected in these power supply lines will flow into a portion of the doped layer to serve as a source. At this point in time, antenna errors could occur in the buried insulator under that portion of the doped layer to serve as a source. That is why the power supply lines need to be subjected to so-called “antenna inspection” and antenna diodes should be inserted thereto.

In a semiconductor integrated circuit comprised of conventional transistors with a so-called “bulk structure,” only the possibility of antenna errors' occurring in its gate dielectric needs to be taken into account. That is why in the case of a semiconductor integrated circuit comprised of SOI transistors, antenna inspection often tends to be carried out negligently on the power supply lines during the physical design process, thus increasing the likelihood of failing to insert antenna diodes due to a human error. Meanwhile, insertion of a capacitor cell, which is one of countermeasures to reduce power supply noise, has already been carried out routinely as a part of the physical design process.

Thus, according to the present disclosure, a capacitor cell 30 with antenna diodes such as the one shown in FIG. 1B is provided in advance as one of standard cells 10 and used for the physical design process. This allows the antenna diodes to be inserted into the power supply lines even if the designer fails to pay special attention during the process step of inserting the capacitor cell. That is to say, this may prevent the designer from failing to insert the antenna diodes inadvertently due to a human error. Consequently, antenna errors may be avoided in a semiconductor integrated circuit with SOI transistors.

In the embodiment described above, a capacitor cell with antenna diodes is supposed to be placed during the physical design process. However, this is only a non-limiting exemplary embodiment of the present disclosure. Alternatively, the rule of the physical design may either stipulate or recommend that the designer arrange an antenna cell adjacent to a capacitor cell. Also, if a capacitor cell and an antenna cell are separately provided for a physical design tool, the antenna cell may be automatically placed adjacent to the capacitor cell being placed.

(First Alternative Configuration)

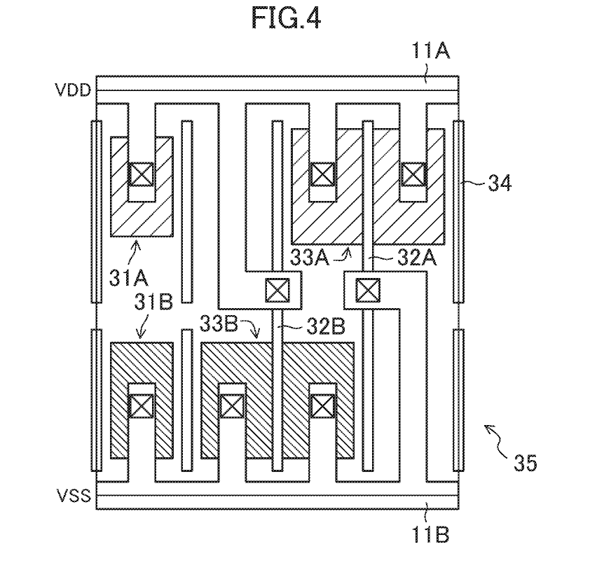

FIG. 4 illustrates an alternative configuration for a capacitor cell with antenna diodes. As in the configuration shown in FIG. 1B, antenna diodes 31A, 31B have been formed in this capacitor cell 35 with antenna diodes between the power supply lines 11A, 11B and the substrate or well. In addition, capacitors 33A, 33B have also been formed between the power supply line 11A for supplying a supply potential VDD and a gate line 32A and between the power supply line 11B for supplying a ground potential VSS and a gate line 32B, respectively. In this embodiment, however, these gate lines 32A, 32B have the same line width as the other gate lines 34, and therefore, have a narrower width than the gate lines 27A, 27B in the configuration shown in FIG. 1B. That is to say, in this capacitor cell 35 with antenna diodes, every gate line has the same line width.

Depending on the requirements for a fine-line process, it may be difficult to broaden the gate line width from the viewpoint of the yield, for example. In that case, the capacitors 33A, 33B may be formed to include these gate lines 32A, 32B with the same line width as the other gate lines as in the layout shown in FIG. 4.

(Second Alternative Configuration)

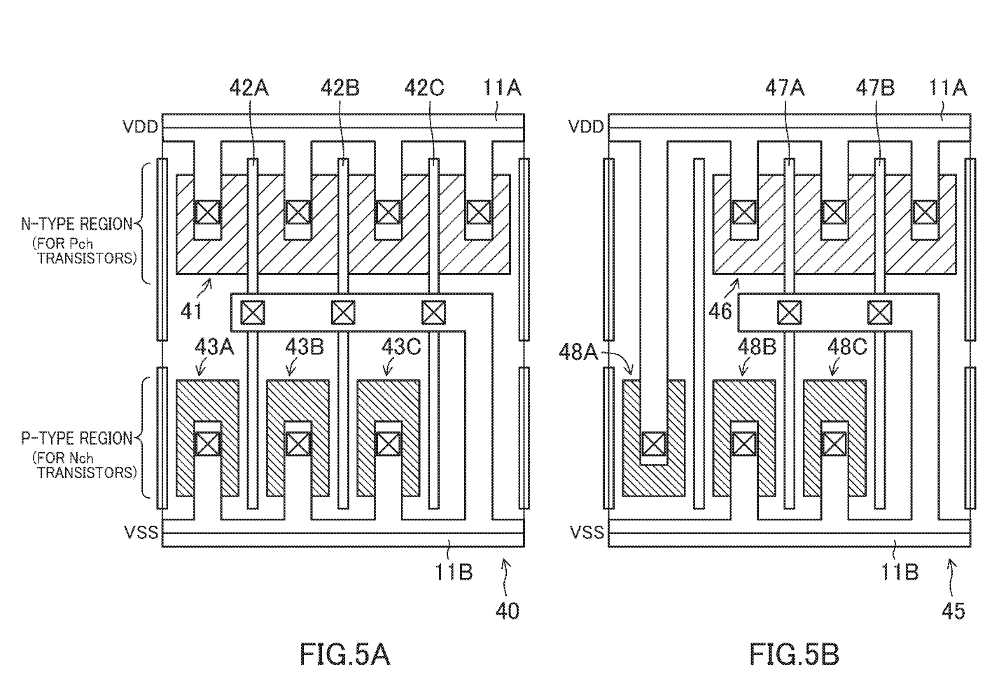

FIGS. 5A and 5B illustrate another alternative configuration for a capacitor cell with antenna diodes. The capacitor cell 40 with antenna diodes shown in FIG. 5A includes a capacitor 41 only in an N-type region where P-channel transistors are arranged, with no capacitors provided in a P-type region where N-channel transistors are arranged. The capacitor 41 includes three gate lines 42A, 42B, and 42C as its constituents. In the configuration illustrated in FIG. 5A, antenna diodes 43A, 43B, and 43C are arranged in only the P-type region. Also, in FIG. 5A, all of these three antenna diodes 43A, 43B, and 43C are connected to the power supply line 11B for supplying the ground potential VSS.

The capacitor cell 45 with antenna diodes shown in FIG. 5B also includes a capacitor 46 only in the N-type region, with no capacitors provided in the P-type region. The capacitor 46 includes two gate lines 47A and 47B as its constituents. In the configuration illustrated in FIG. 5B, antenna diodes 48A, 48B, and 48C are arranged in only the P-type region. Also, in FIG. 5B, the antenna diode 48A is connected to the power supply line 11A for supplying the supply potential VDD, while the other two antenna diodes 48B and 48C are connected to the power supply line 11B for supplying the ground potential VSS.

In general, a capacitor cell can have no capacitors in either a P-type region or an N-type region due to an insufficient breakdown voltage or for any other reason. In that case, antenna diodes may be arranged in one of the P- and N-type regions that has no capacitors (e.g., the P-type region in this example) as in the layouts shown in FIGS. 5A and 5B. In this case, the antenna diodes arranged may be all connected to the closer power supply line as shown in FIG. 5A. Alternatively, only some of those antenna diodes may be connected to the more distant power supply line as shown in FIG. 5B. That is to say, only VSS antenna diodes are provided in FIG. 5A, whereas both a VDD antenna diode and VSS antenna diodes are provided in FIG. 5B.

In the examples illustrated in FIGS. 5A and 5B, a capacitor is arranged in the N-type region and antenna diodes are arranged in the P-type region. However, this is only a non-limiting exemplary embodiment. Conversely, a capacitor may be arranged in the P-type region and antenna diodes may be arranged in the N-type region.

(Third Alternative Configuration)

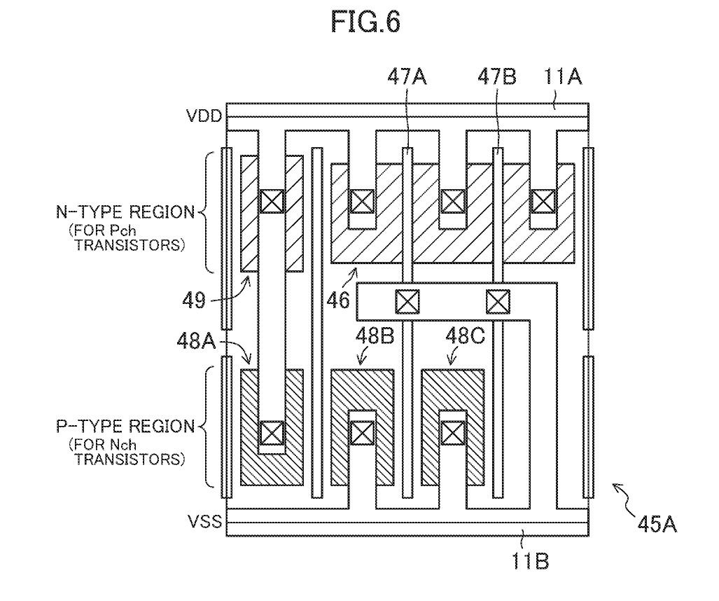

FIG. 6 illustrates still another alternative exemplary configuration for a capacitor cell with antenna diodes. The capacitor cell 45A with antenna diodes shown in FIG. 6 is a variation of the configuration shown in FIG. 5B. Thus, any component also shown in FIG. 5B and having substantially the same function as its counterpart shown in FIG. 5B is identified by the same reference numeral as the counterpart's, and a detailed description thereof will be omitted herein to avoid redundancies. In the configuration shown in FIG. 6, another antenna diode 49 is further provided as an additional component in the N-type region. That is to say, both the capacitor 46 and the antenna diode 49 are arranged in the N-type region. Such a capacitor cell with antenna diodes, in which a capacitor is arranged in either the N-type region or the P-type region and in which at least one antenna diode is arranged in both of the N-type and P-type regions, may also be used.

The above-described layouts for a capacitor cell with antenna diodes are only examples, and do not limit the scope of the present disclosure in any way. Optionally, a semiconductor integrated circuit may also be laid out with multiple different types of layouts adopted in combination for a capacitor cell with antenna diodes.

Note that it does not make any significant difference no matter whether the VDD antenna diodes are arranged in the P-type region or the N-type region and/or formed on a well or the substrate. The same remarks also apply to the VSS antenna diodes.

The present disclosure allows a semiconductor integrated circuit with SOI transistors to avoid causing antenna errors involved with power supply lines, and therefore, does contribute to enhancing the yield of very-large-scale integrated circuits (VLSIs), for example.

What is claimed is:

1. A layout structure for a semiconductor integrated circuit including silicon-on-insulator (SOI) transistors, the structure comprising:
a circuit block in which a plurality of standard cells are arranged, thereby forming a circuit of the SOI transistors, wherein
the circuit block includes a capacitor cell including a capacitor arranged between a first power supply line for supplying a supply potential and a second power supply line for supplying a ground potential, and
the capacitor cell includes an antenna diode formed between either the first or second power supply line and either a substrate or a well, or
an antenna cell, including an antenna diode formed between either the first or second power supply line and either the substrate or the well, is arranged adjacent to the capacitor cell.

2. The layout structure of claim 1, wherein
the capacitor included in the capacitor cell includes a gate line and a doped region.

3. The layout structure of claim 2, wherein
gate lines of the capacitor cell all have the same line width.

4. The layout structure of claim 2, wherein
the capacitor cell includes the antenna diode, and
the capacitor is arranged in either a P-type region or an N-type region.

5. The layout structure of claim 4, wherein
the antenna diode of the capacitor cell includes an antenna diode arranged in the P-type region and an antenna diode arranged in the N-type region.
